(19) United States
(12) Patent Application Publication
(10) Pub. No.: US 2021/0253485 A1
(43) Pub. Date: Aug. 19, 2021

(54) TUBULAR BODY CONTAINING SiC FIBERS

(71) Applicant: FERROTEC HOLDINGS CORPORATION, Tokyo (JP)

(72) Inventors: Fumitomo Kawahara, Okayama (JP); Shougo Tsunagi, Okayama (JP)

(21) Appl. No.: 17/269,749

(22) PCT Filed: Sep. 13, 2018
(86) PCT No.: PCT/JP2018/034061

§ 371 Date: Feb. 19, 2021

(30) Foreign Application Priority Data
Aug. 20, 2018 (JP) 2018-153921

(51) Int. Cl. C04B 35/628; C23C 16/32; C04B 35/565; C04B 41/87

(52) U.S. Cl. CPC C04B 35/62863; C04B 41/87; C04B 35/565; C23C 16/325

(57) ABSTRACT

Provided is a tubular body containing SiC fibers having high thermal conductivity. The tubular body containing SiC fibers includes a SiC fiber layer wound in a tubular form, an inner SiC coating layer covering an inner surface of the SiC fiber layer, and an outer SiC coating layer covering an outer surface of the SiC fiber layer. The inner and outer SiC coating layers are bound to each other in gaps provided in the SiC fiber layer.

### TECHNICAL FIELD

The present invention relates to a tubular body containing SiC fibers that is particularly applicable to, for example, nuclear fuel cladding tubes.

### BACKGROUND ART

Zircaloy (an alloy of zirconium) that is low in neutron absorption and has corrosion resistance and mechanical strength has been widely used for cladding tubes for storing nuclear fuel.

Zircaloy, however, has properties of reacting with the surrounding water (coolant) and generating hydrogen when it reaches a specific temperature. This reaction is an exothermic reaction that involves a rapid temperature rise, and thus has been one of the causes for loss of nuclear power control resulting in serious accidents.

Some cladding tubes including SiC (silicon carbide) have been recently proposed. Silicon carbide is a material that is resistant to heat, chemically stable, and light in weight, and has high mechanical strength, good neutron economy, and low reactivity with water.

The tubular body disclosed in Patent Document 1 includes first and second SiC-fiber-reinforced SiC composite materials and a cushioning material that partially joins the first and second SiC-fiber-reinforced SiC composite materials. The first and second SiC-fiber-reinforced SiC composite materials are each composed of an aggregate, made of SiC fibers, and a SiC matrix. The SiC matrix is composed of a filler made of a PIP-SiC material that fills the gaps in the aggregate made of SiC fibers, and a coating material made of a CVD-SiC material that covers the aggregate and the filler. Such a configuration makes the cladding tube strong to prevent distortion.

The gaps between the SiC fibers in this tubular body, however, are filled with the filler made of the RIP-SiC material. The RIP-SiC material is porous, in other words, has voids. This has been a cause of poor thermal conductivity and low energy efficiency.

### PRIOR ART DOCUMENT

### Patent Document

Patent Document 1: Japanese Unexamined Patent Application Publication No. 2016-135727

### SUMMARY OF THE INVENTION

### Problems to be Solved by the Invention

In view of the above-described problems of the prior art, an object of the present invention is to provide a tubular body containing SiC fibers having high thermal conductivity.

### Means for Solving the Problems

The present invention provides a tubular body containing SiC fibers as first means for solving the above-described problems. The tubular body comprises a SiC fiber layer wound in a tubular form, an inner SiC coating layer covering an inner surface of the SiC fiber layer, and an outer SiC coating layer covering an outer surface of the SiC fiber layer.

The inner SiC coating layer and the outer SiC coating layer are bound to each other in gaps provided in the SiC fiber layer.

The first means provides a tubular body having high thermal conductivity and mechanical strength.

The present invention provides, as second means for solving the above-described problems, the tubular body containing SiC fibers according to the first means in which the inner SiC coating layer is composed of sintered SiC.

The second means eliminates necessity of removing a base material (such as a graphite base material) in a later process, whereas removal of a CVD-SiC layer is necessary. The present invention can be easily applied, in particular, to elongated members.

The present invention provides, as third means for solving the above-described problems, the tubular body containing SiC fibers according to the first and second means in which the tubular body has a cross-sectional shape of a polygon, circle, ellipse, or round shape having irregularities on an outer circumference thereof.

The third means enables the tubular body containing SiC fibers to be more widely used.

### Effects Of The Invention

According to the present invention, the inner and outer SiC coating layers are bound to each other in the gaps provided in the SiC fiber layer, which configuration provides a tubular body having high thermal conductivity and mechanical strength. Application of the present invention to a cladding tube that serves as a heat exchanger leads to provision of a nuclear reactor having high energy efficiency. Further, this can reduce consumption of fuel, i.e. uranium, and shorten the period for maintaining the nuclear reactor, which in turn enhances the operational efficiency of the entire nuclear reactor.

### BRIEF DESCRIPTION OF THE DRAWINGS

FIG. 1 is a perspective view showing a tubular body containing SiC fibers of the present invention.

FIG. 2 shows partial cross-sections of the tubular body containing SiC fibers of the present invention.

### MODE FOR CARRYING OUT THE INVENTION

An embodiment of a tubular body containing SiC fibers of the present invention will be described in detail below with reference to the accompanying drawings.

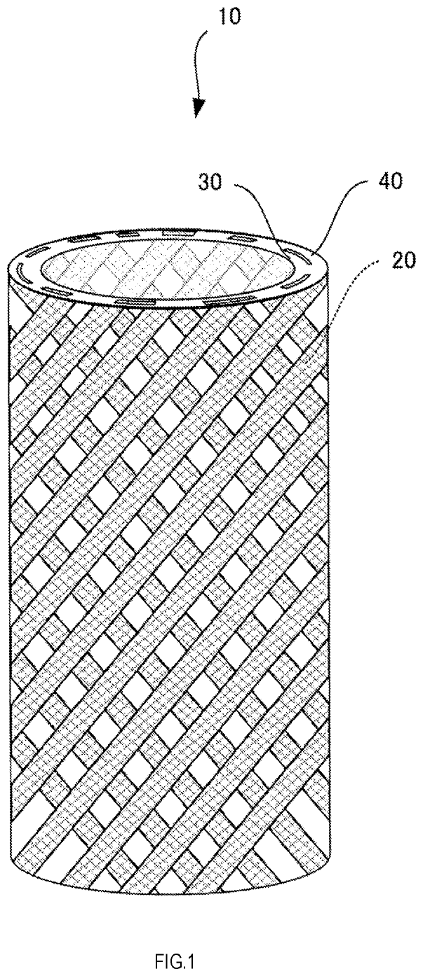

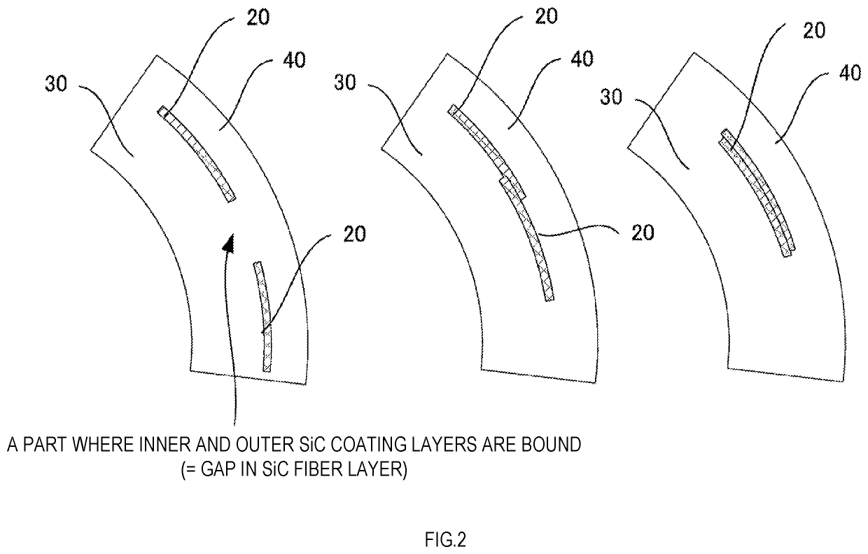

FIG. 1 is a perspective view showing the tubular body containing SiC fibers. FIG. 2 shows partial cross-sections of the tubular body containing SiC fibers of the present invention.

A tubular body 10 containing SiC fibers of the present invention comprises a SiC fiber layer 20 wound in a tubular form, an inner SiC coating layer 30 covering the inner surface of the SiC fiber layer 20, and an outer SiC coating layer 40 covering the outer surface of the SiC fiber layer 20.

The SiC fiber layer 20 has a structure in which the SiC fibers are bundled into strands, braided, and helically wound to enhance combined effect. The SiC fiber layer 20 is provided with patterned gaps (voids) between the intersecting fibers (see FIG. 1).

The inner SiC coating layer 30 is formed, for example, in a CVD furnace at 1000° C. to 1400° C. by supplying SiCl₄ and CH₄ together with H₂ that acts as a diluent gas. The formed CVD-SiC film has a thickness of, for example, about 300 μm. The inner SiC coating layer 30 is not required to have as much corrosion resistance as the outer SiC coating layer; it is thus possible to use a sintered SiC material, for example.

Similarly to the inner SiC coating layer 30, the outer SiC coating layer 40 is formed, for example, in a CVD furnace at 1000° C. to 1400° C. by supplying SiCl₄ and CH₄ together with H₂ that acts as a diluent gas. The formed CVD-SiC film has a thickness of, for example, about 500 μm.

The inner and outer SiC coating layers 30, 40 are tightly and closely bound to each other in the gaps provided in the SiC fiber layer 20 (see FIG. 2). Specifically, the outer SiC coating layer 40 is made thicker than the inner SiC coating layer 30, which configuration allows film formation in the gaps as well as on the surface of the SiC fiber layer 20. Such coating layers are bound to each other while interposing the SiC fiber layer 20 in between due to binding of the materials of the SiC layers that are identical in terms of, for example, thermal expansion rates. Accordingly, layer separation is less likely to occur. In the structure of the inner and outer SiC coating layers (with the SiC fiber layer in between), these layers may be stacked multiple times in repetition.

The cross-sectional shape of the tubular body may be a circle, ellipse, polygon, such as triangle and quadrangle, or round shape having irregularities on the outer circumference thereof. Accordingly, the tubular body containing SiC fibers can be more widely used.

The following describes a method for producing the tubular body 10 containing SiC fibers of the present invention, which is configured as described above. Examples of the method for producing the tubular body containing SiC fibers of the present invention include a method that involves use of a graphite base material or sintered SiC, which will be described below.

[Graphite Base Material]

Step 1: Preparing Graphite Base Material

A graphite base material is prepared that does not react in a later process such as in CVD treatment. The graphite base material is shaped into a round bar having a specified diameter and length.

Step 2: Coating Inner SiC

A SiC film is formed on the entire surface (the outer peripheral surface) of the graphite base material by CVD method (Chemical Vapor Deposition method). The SiC film has a thickness of about 300 μm.

Step 3: Winding First SiC Fiber Layer

SiC fibers are wound into strands and braided to be helically wound by a commercially available automatic loom around the surface of the graphite base material coated with the inner SiC film.

Step 4: Forming Outer SiC Coating Layer

Similarly to the inner SiC coating layer, a SiC film is formed on the entire surface (on the outer peripheral surface) of the graphite base material with the SiC fibers wound therearound by the CVD method. The SiC film has a thickness of about 500 μm.

Step 5: Outer Shape Processing

The outer shape of the outer SiC coating layer is adjusted by, for example, cutting.

Step 6: Winding Second SiC Fiber Layer

Similarly to the first SiC fiber layer, the SiC fibers are wound into strands and braided to be helically wound by a commercially available automatic loom around the surface of the graphite base material coated with the outer SiC film.

Step 7: Forming Outer SiC Coating Layer

A SiC film is formed on the entire outer peripheral surface of the graphite base material with the SiC fibers wound therearound by the CVD method. The SiC film has a thickness of, for example, about 500 μm.

Step 8: Cutting/Severing of Outer Shape/Length

The outer shape (diameter, length, and so on) of the tubular body obtained in Step 7 is adjusted by machining (cutting, severing, or other machining technique).

Step 9: Removing Graphite Base Material

The graphite base material is removed in a high-temperature and oxidizing environment.

Step 10: Shaping

The tubular body is ground or polished, and then chamfered and cleaned.

[Sintered SiC]

Step 20: Preparing Sintered SiC Base Material

A pipe-shaped sintered SiC base material is prepared. The sintered SiC base material can be produced by, for example, extrusion molding to make a green body and then sintering of the green body at 2200 ° C. in an inert gas.

Step 21: Coating Inner SiC

A SiC film is formed on the entire surface (outer peripheral surface) of the sintered SiC base material by CVD method (Chemical Vapor Deposition method). The SiC film has a thickness of about 300 μm. Use of the tubular sintered SiC base material allows omission of forming the CVD-SiC layer in Step 21.

Step 22: Winding First SiC Fiber Layer

The SiC fibers are wound into strands and braided to be helically wound by a commercially available automatic loom around the surface of the sintered SiC base material coated with the inner SiC film.

Step 23: Forming Outer SiC Coating Layer

Similarly to the inner SiC coating layer, a SiC film is formed on the entire surface (on the outer peripheral surface) of the sintered SiC base material with the SiC fibers wound therearound by the CVD method. The SiC film has a thickness of about 500 μm.

Step 24: Outer Shape Processing

If necessary, the outer shape of the outer SiC coating layer is adjusted by, for example, cutting.

Step 25: Winding Second SiC Fiber Layer

Similarly to the first SiC fiber layer, the SiC fibers are bundled into strands and braided by a commercially available automatic loom to be wound around the surface of the sintered SiC base material coated with the outer SiC film.

Step 26: Forming Outer SiC coating Layer

A SiC film is formed on the entire outer peripheral surface of the sintered SiC base material with the SiC fibers wound therearound by the CVD method. The SiC film has a thickness of about 500 μm.

Step 27: Cutting/Severing of Outer Shape/Length

The outer shape (diameter, length, and so on) of the tubular body obtained in Step 26 is adjusted by machining (cutting, severing, or machining technique).

Step 28: Shaping

The tubular body is ground or polished, and then chamfered and cleaned.

The above has described a method for producing a tubular body having two SiC fiber layers; it is also possible to produce a tubular body having only one SiC fiber layer or three or more SiC fiber layers.

According to the above-described present invention, the inner and outer SiC coating layers are bound to each other in the gaps provided in the SiC fiber layer. This configuration provides a tubular body having high thermal conductivity and mechanical strength.

A preferred embodiment of the present invention has been described above. The present invention, however, should not be limited to the above-described embodiment; various modifications can be made without departing from the gist of the present invention.

Further, the present invention should not be limited to combinations described in the embodiment; the present invention can be implemented by various combinations.

### INDUSTRIAL APPLICABILITY

The present invention can be widely applied to, for example, cladding tubes for storing nuclear fuel.

### EXPLANATION OF REFERENCE NUMERALS

10 tubular body containing SiC fibers

20 SiC fiber layer

30 inner SiC coating layer

40 outer SiC coating layer

1. A tubular body containing SiC fibers, the tubular body comprising:
a SiC fiber layer wound in a tubular form;
an inner SiC coating layer covering an inner surface of the SiC fiber layer; and
an outer SiC coating layer covering an outer surface of the SiC fiber layer,
wherein the inner SiC coating layer and the outer SiC coating layer are bound to each other in gaps provided in the SiC fiber layer.

2. The tubular body containing SiC fibers according to claim 1,
wherein the inner SiC coating layer is composed of sintered SiC.

3. The tubular body containing SiC fibers according to claim 1,
wherein the tubular body has a cross-sectional shape of a polygon, circle, ellipse, or round shape having irregularities on an outer circumference thereof.
